(19) United States
(12) Patent Application Publication
(10) Pub. No.: US 2026/0156784 A1
(43) Pub. Date: Jun. 4, 2026

(54) HEAT DISSIPATION BRACKET AND ELECTRICAL CONTROL COMPONENT EMPLOYING BRACKET

(71) Applicant: HON HAI PRECISION INDUSTRY CO., LTD., New Taipei (TW)

(72) Inventors: YU-SHENG CHANG, New Taipei (TW); WEN-BIN HUANG, New Taipei (TW); HSIU-FU LI, New Taipei (TW); YUAN-LUNG HSU, New Taipei (TW); MIN-HORNG HSU, New Taipei (TW); KAI-CHENG CHAO, New Taipei (TW)

(21) Appl. No.: 19/062,234

(22) Filed: Feb. 25, 2025

(30) Foreign Application Priority Data
Nov. 29, 2024 (CN) 202411742623.6

(51) Int. Cl. H05K 7/20

(52) U.S. Cl. CPC H05K 7/2039

(57) ABSTRACT

A heat dissipation bracket includes a plurality of heat dissipation plates, a first side plate, and a second side plate. The plurality of heat dissipation plates defines a length direction, a width direction, and a thickness direction. The plurality of heat dissipation plates is arranged at intervals along the thickness direction, each heat dissipation plate is provided with a first flow passage and a second flow passage separated along the width direction. The first side plate is provided with a first chamber, a second chamber, a water inlet, and a water outlet. The first chamber and the second chamber are arranged at intervals along the width direction, the water inlet is connected with the first chamber, and the water outlet is connected with the second chamber. The second side plate is provided with a plurality of connection passages. An electrical control component is also provided.

### FIELD

The present disclosure relates to field of heat dissipation of equipment, and in particular to a heat dissipation bracket and an electrical control component.

### BACKGROUND

Current heat dissipation brackets are difficult to dissipate heat for multiple object components (such as electrical control boxes) at the same time, a heat dissipation efficiency of the heat dissipation bracket is low.

Thus, there is room for improvement within the art.

### BRIEF DESCRIPTION OF THE DRAWINGS

Many aspects of the disclosure can be better understood with reference to the following drawings. The assemblies in the drawings are not necessarily drawn to scale, the emphasis instead being placed upon clearly illustrating the principles of the disclosure. Moreover, in the drawings, like reference numerals designate corresponding parts throughout the several views.

FIG. 1 shows a three-dimensional schematic diagram illustrating a structure of a heat dissipation bracket according to an embodiment of the present application.

FIG. 2 shows a cutaway diagram illustrating the heat dissipation bracket along a A-A line in FIG. 1. An object component is also shown in FIG. 2.

FIG. 3 shows a three-dimensional schematic diagram illustrating a structure of a heat dissipation plate in FIG. 1.

FIG. 4 shows a three-dimensional schematic diagram illustrating a structure of a first side plate in FIG. 1.

FIG. 5 shows an exploded schematic diagram illustrating the structure of the first side plate in FIG. 4.

FIG. 6 shows a three-dimensional schematic diagram illustrating a structure of a second side plate in FIG. 1.

FIG. 7 shows an exploded schematic diagram illustrating the structure of the second side plate in FIG. 6.

### DETAILED DESCRIPTION

In order to make the above-mentioned objects, features and advantages of the present application more obvious, a detailed description of specific embodiments of the present application will be described in detail with reference to the accompanying drawings. A number of details are set forth in the following description so as to fully understand the present application. However, the present application can be implemented in many other ways different from those described herein, and those skilled in the art can make similar improvements without violating the contents of the present application. Therefore, the present application is not to be considered as limiting the scope of the embodiments described herein.

Several definitions that apply throughout this disclosure will now be presented.

In the description of the present disclosure, it should be understood that the terms “upper”, “lower”, “inner”, “outer”, “axial”, “radial”, “circumference”, etc. indicate the orientation or positional relationship based on the orientation or positional relationship shown in the drawings, it is only for the convenience of describing the present disclosure and simplifying the description, rather than indicating or implying that the device or element referred to must have a specific orientation, be constructed and operated in a specific orientation, and therefore it cannot limit the present disclosure.

In the description of the present disclosure, it should be noted that the terms “installed”, “connecting”, and “connected” should be interpreted broadly unless otherwise clearly specified and limited. For example, they can be fixed or detachable connected or integrally connected; they can be directly connected, or indirectly connected through intermediate components, and they can be the internal connections between two components. For those of ordinary skill in the art, the specific meanings of the above-mentioned terms in the present disclosure can be understood in specific situations.

Unless otherwise defined, all technical and scientific terms used herein have the same meaning as commonly understood by one skilled in the art. The terms used in a specification of the present application herein are only for describing specific embodiments and are not intended to limit the present application. The terms “and/or” used herein includes any and all combinations of one or more of associated listed items.

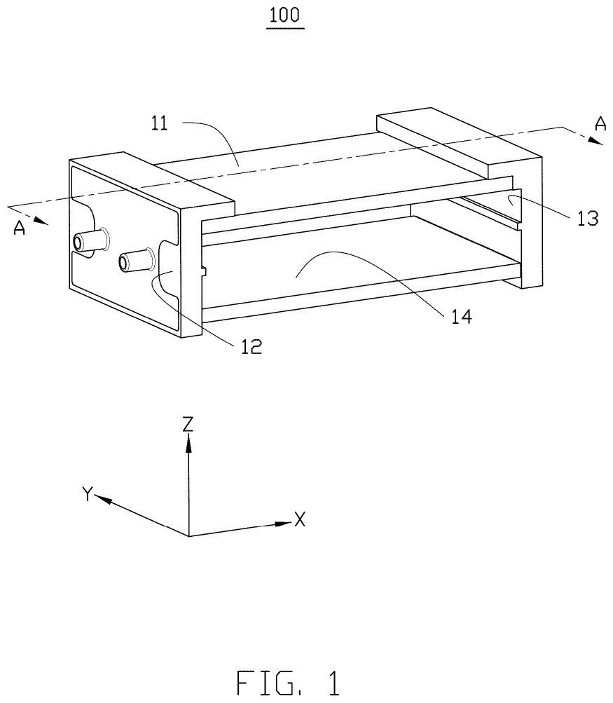

Referring to FIG. 1, one embodiment provides an electrical control component 1000. The electrical control component 1000 may include a heat dissipation bracket 100 and a plurality of object components 10. Each of the plurality of object components 10 can be arranged in the heat dissipation bracket 100 to dissipate heat through the heat dissipation bracket 100.

In one embodiment, the electrical control component 1000 can be used to control a motor of a vehicle. The object component 10 may be an electrical control box for controlling the motor of the vehicle. The electrical control box may generate heat during operating, and the electrical control box is dissipated heat through the heat dissipation bracket 100, which can ensure that the electrical control box operates at a normal working temperature.

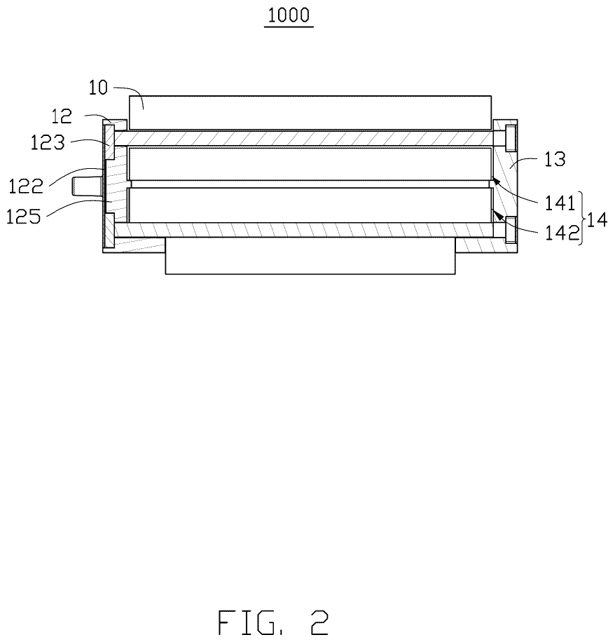

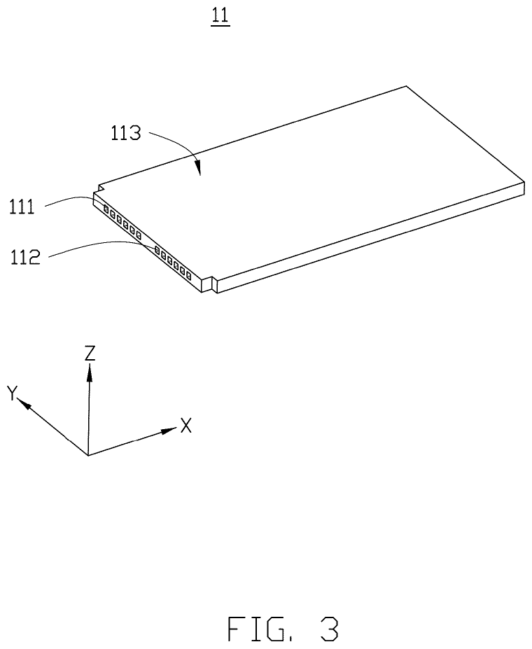

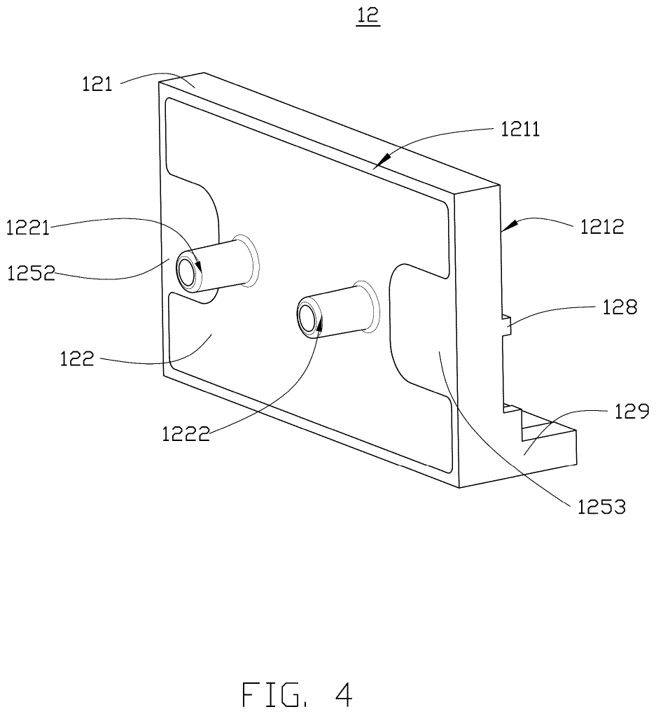

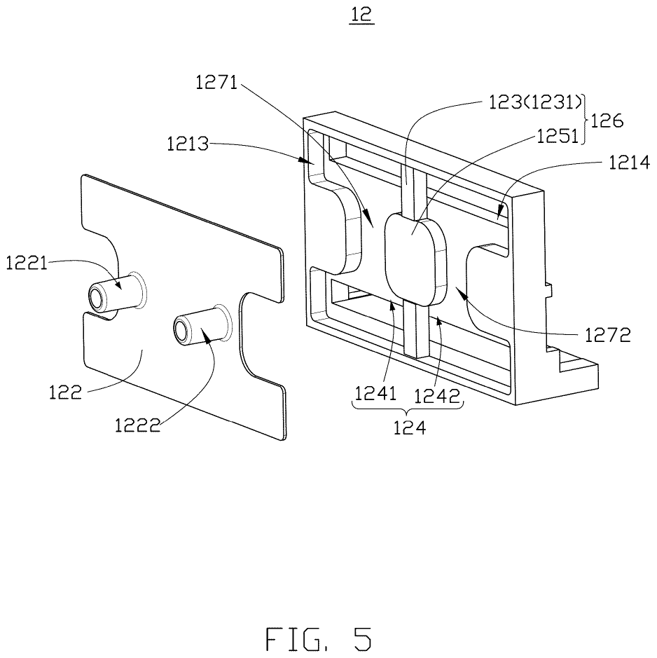

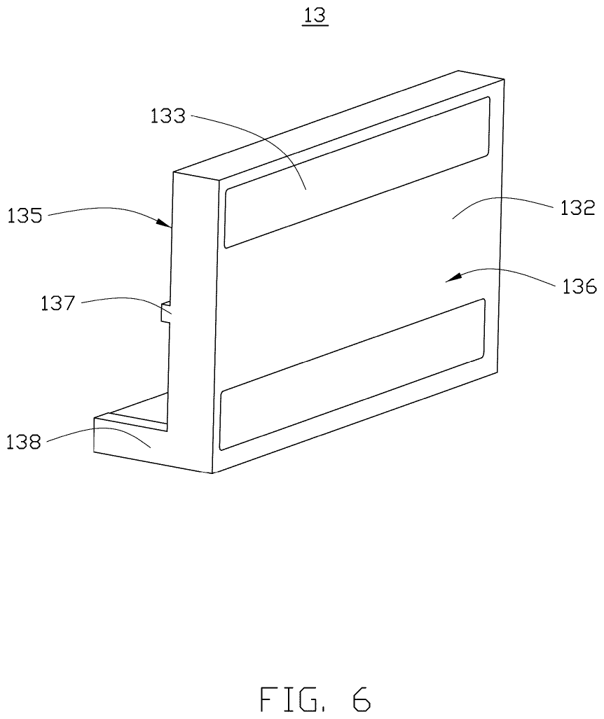

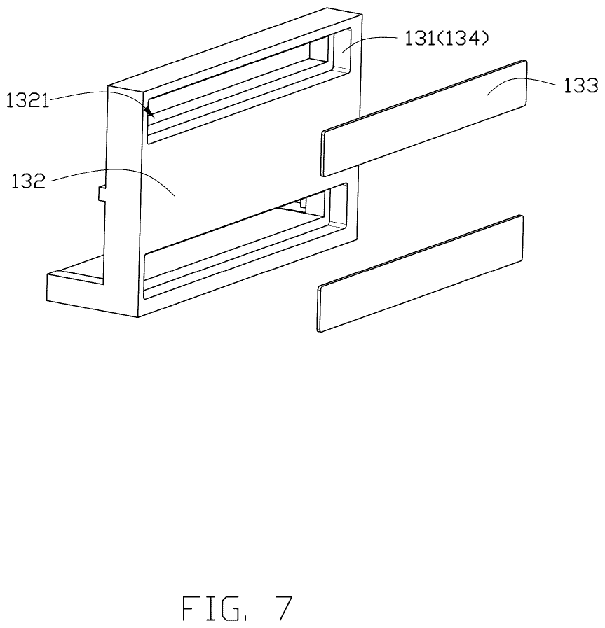

Referring to FIG. 2 to FIG. 7, the heat dissipation bracket 100 may include a plurality of heat dissipation plates 11, a first side plate 12, and a second side plate 13. The plurality of heat dissipation plates 11 defining a length direction X, a width direction Y, and a thickness direction Z. The plurality of heat dissipation plates 11 is arranged at intervals along the thickness direction Z. Each of the plurality of heat dissipation plates 11 is provided with a first flow passage 111 and a second flow passage 112 separated along the width direction Y. The first side plate 12 is provided with a first chamber 1241 and a second chamber 1242, the first chamber 1241 and the second chamber 1242 are arranged at intervals along the width direction Y. The first side plate 12 is further provided with a water inlet 1221 and a water outlet 1222, the water inlet 1221 is connected with the first chamber 1241, and the water outlet 1222 is connected with the second chamber 1242. The second side plate 13 is provided with a plurality of connection passages 131.

In one embodiment, each of the plurality of heat dissipation plates 11 is respectively connected between the first side plate 12 and the second side plate 13. An installation space 14 is existed between two adjacent heat dissipation plates 11, and the installation space 14 is configured for installing one object component 10. For each of the plurality of heat dissipation plates 11, one end of the first flow passage 111 close to the first side plate 12 is connected with the first chamber 1241, one end of the second flow passage 112 close to the first side plate 12 is connected with the second chamber 1242, and one end of the first flow passage 111 close to the second side plate 13 and one end of the second flow passage 112 close to the second side plate 13 are connected with a corresponding connection passage 13.

In one embodiment, the plurality of heat dissipation plates 11 arranged at intervals can dissipate heat for the plurality of object components 10 simultaneously, and a heat dissipation efficiency of the heat dissipation bracket 100 is high.

In one embodiment, cooling liquid enters the heat dissipation bracket 100 from the water inlet 1221, and flows out of the heat dissipation bracket 100 from the water outlet 1222 after passing through the first flow passage 111, the connection passage 131, the second flow passage 112, and the second chamber 1242 in turn. During this process, the cooling liquid takes away the heat of the object component 10, thereby cooling the object component 10.

In one embodiment, the first side plate 12 may include a first plate body 121, a first cover plate 122, and a sealing structure 123. The first plate body 121 and the first cover plate 122 are enclosed to form an internal chamber 124, the sealing structure 123 is arranged in the internal chamber 124, and the internal chamber 124 is divided into the first chamber 1241 and the second chamber 1242 by the sealing structure 123. The water inlet 1221 and the water outlet 1222 are respectively arranged on the first cover plate 122.

In one embodiment, the sealing structure 123 is arranged in the internal chamber 124 and connected with two side walls of the internal chamber 124, to divide the internal chamber 124 into the first chamber 1241 and the second chamber 1242.

In one embodiment, the water inlet 1221 is connected to the first chamber 1241, so that the cooling liquid can enter the first chamber 1241 through the water inlet 1221. The water outlet 1222 is connected to the second chamber 1242, so that the cooling liquid can flow out of the second chamber 1242 through the water outlet 1222.

In one embodiment, the first plate body 121 may include a first surface 1211 and a second surface 1212. The first surface 1211 is located on a side of the first plate body 121 deviating from the second side plate 13, and the second surface 1212 is located on a side of the first plate body 121 toward the second side plate 13. The first plate body 121 is provided with a first groove 1213 and a plurality of first installation grooves 1214, the first groove 1213 is formed by an inward concave of the first surface 1211, and the plurality of first installation grooves 1214 penetrates from a bottom surface of the first groove 1213 to the second surface 1212. The first cover plate 122 covers the first groove 1213 to form the internal chamber 124. One end of the plurality of heat dissipation plates 11 near the first side plate 12 are respectively installed on the plurality of first installation grooves 1214.

In one embodiment, the first side plate 12 may further comprise a convex island structure 125. The convex island structure 125 protrudes from the bottom surface of the first groove 1213 and abuts against the first cover plate 122, and the convex island structure 125 is located between two adjacent first installation grooves 1214. The convex island structure 125 may include a middle island 1251. The sealing structure 123 may include two sealing blocks 1231, the two sealing blocks 1231 are respectively connected to two sides of the middle island 1251. The middle island 1251 and the two sealing blocks 1231 jointly form a separation structure 126, and the separation structure 126 divides the internal chamber 124 into the first chamber 1241 and the second chamber 1242.

In one embodiment, the heat dissipation plate 11 extends into the first installation groove 1214 and the heat dissipation plate 11 is installed in the installation groove 1214 in a matching way, thus the first flow passage 111 is connected to the first chamber 1241 and the second flow passage 112 is connected to the second chamber 1242.

In one embodiment, the sealing blocks 1231 are connected to two sides of the convex island structure 125 facing two first grooves 1213 respectively, to form the separation structure 126. Two ends of the separation structure 126 are connected to two side walls of the internal chamber 124 respectively, and the internal chamber 124 is divided into the first chamber 1241 and the second chamber 1242.

In one embodiment, the sealing blocks 1231 can be made of colloid materials. In other embodiments, the sealing blocks 1231 may be made of other sealing materials.

In one embodiment, the convex island structure 127 may further include a first side island 1252 and a second side island 1253. The first side island 1252 is located in the first chamber 1241, and the first side island 1252 is separated from the middle island 1251 to form a first passage 1271. A width of the first passage 1271 is less than a width of a portion of the first installation groove 1214 located in the first chamber 1241. The second side island 1253 is located in the second chamber 1242, and the second side island 1253 is separated from the middle island 1251 to form a second passage 1272. A width of the second passage 1272 is less than a width of a portion of the first installation groove 1214 located in the second chamber 1242. The water inlet 1221 is corresponded to the first passage 1271 along the length direction X, and the water outlet 1222 is corresponded to the second passage 1272 along the length direction X.

In one embodiment, the water inlet 1221 is connected to a middle of the first passage 1271, the cooling liquid can enter into the first passage 1271 through the water inlet 1221 and flow to both sides along the first passage 1271.

In one embodiment, the water outlet 1222 is connected to a middle of the second passage 1272, the cooling liquid can flow from the second flow passage 112 to the middle of the second passage 1272 and then flow out.

In one embodiment, the first side island 1252 is cooperated with the middle island 1251 to form the first passage 1271, and the cooling liquid flows into the first passage 1271 through the water inlet 1221. The width of the first passage 1271 is less than the width of the part of the first installation groove 1214 located in the first chamber 1241, thus the cooling liquid can be directed into the first flow passage 111.

In one embodiment, the second side plate 13 may include a second plate body 132 and a plurality of second cover plates 133. The second plate body 132 is provided with a plurality of second grooves 134, and the plurality of second cover plates 133 respectively cover the plurality of second grooves 134 to form the plurality of connection passages 131.

In one embodiment, two ends of the connection passages 131 are connected to the first flow passage 111 and the second flow passage 112 respectively, to direct the cooling liquid flow from the first flow passage 111 to the second flow passage 112.

In one embodiment, the second side plate 13 may further include a third surface 135 and a fourth surface 136. The third surface 135 is located on a side of the second plate body 132 toward the first side plate 12, and the fourth surface 136 is located on a side of the second plate body 132 away from the first side plate 12. The second plate body 132 is further provided with a second installation groove 1321, the second installation groove 1321 penetrates from a bottom surface of the second groove 134 to the third surface 135. One end of the plurality of heat dissipation plates 11 near the second side plate 13 are arranged in the second installation groove 1321 and connected with the plurality of connection passages 131.

In one embodiment, the number of the second installation groove 1321 can be one or more. The heat dissipation plates 11 are installed in the second installation groove 1321, thus the first flow passage 111 and the second flow passage 112 are connected to the connection passages 131, and the cooling liquid can flow into the connection passages 131 through the first flow passage 111 and then flow into the second flow passage 112.

In one embodiment, the heat dissipation plates 11 can be cuttable structures. By cutting the heat dissipation plates 11, lengths of the heat dissipation plates 11 can be reduced, a distance between the first side plate 12 and the second side plate 13 can also be reduced, thus the heat dissipation plates 11 can match the object components 10 with different lengths.

In one embodiment, the first side plate 12 may include the second surface 1212. The second surface 1212 is located on a side of the first side plate 12 toward the second side plate 13. The second side plate 13 may include the third surface 135, and the third surface 135 is located on a side of the second side plate 13 toward the first side plate 12. The first side plate 12 may further include a first limiting boss 128 protruding from the second surface 1212, and the second side plate 13 may further include a second limiting boss 137 protruding from the third surface 135. The first limiting boss 128 is arranged opposite the second limiting boss 137 along the length direction X. The installation space 14 may include a first subspace 141 and a second subspace 142, the first subspace 141 and the second subspace 142 are located on either side of the first limiting boss 128 and the second limiting boss 137 respectively. The first subspace 141 and the second subspace 142 are respectively configured to accommodate one object component 10.

In one embodiment, the first limiting boss 128 and the second limiting boss 137 are arranged relative to each other along the length direction X and divide the installation space 14 into the first subspace 141 and the second subspace 142. When the object component 10 is installed in the first subspace 141 and the second subspace 142, one end of the object component 10 along the thickness direction Z abuts against the heat dissipation plate 11 on one side, and the other end of the object component 10 is connected to the first limiting boss 128 and the second limiting boss 137. Thus, the object component 10 is sandwiched between the heat dissipation plate 11 and a side of the first limiting boss 128 and the second limiting boss 137 facing the heat dissipation plate 11.

In one embodiment, the first side plate 12 may include the second surface 1212, and the second surface 1212 is located on a side of the first side plate 12 toward the second side plate 13. The second side plate 13 may include the third surface 135, and the third surface 135 is located on a side of the second side plate 13 toward the first side plate 12. The first side plate 12 may further include a first support platform 129 protruding from the second surface 1212, and the second side plate 13 may further include a second support platform 138 protruding from the third surface 135. The first support platform 129 and the second support platform 138 are respectively configured to support two ends of the length direction X of an object heat dissipation plate 11 which is located at the lowest layer. A space between the first support platform 129 and the second support platform 138 is configured to be capable of installing one object component 10.

The object heat dissipation plate 11 is one of the plurality of heat dissipation plates which is located at the lowest layer.

In one embodiment, the first support platform 129 and the second support platform 138 are opposite each other in the length direction X and form an installation gap. The installation gap is cooperated with two ends of the object component 10 along the length direction X, to clamp the object component 10 between the first support platform 129 and the second support platform 138.

In one embodiment, each of the plurality of heat dissipation plates 11 may include two heat dissipation surfaces 113, and the two heat dissipation surfaces 113 are arranged oppositely along the thickness direction Z. Each of the two heat dissipation surfaces 113 is configured for conducting heat in contact with the object component 10.

In one embodiment, the heat dissipation plate 11 is connected with the object component 10 on both sides of the heat dissipation surface 113 along the thickness direction Z, to dissipate multiple object components 10 at the same time and improve the heat dissipation efficiency.

The embodiments of the heat dissipation bracket 100 is configured with the first side plate 12 and the second side plate, the first side plate 12 and the second side plate are arranged relative to each other, the plurality of heat dissipation plates 11 are sandwiched between the first side plate 12 and the second side plate 13, and the plurality of heat dissipation plates 11 are arranged at intervals to form the installation space 14. The surfaces of the first side plate 12 and the second side plate 13 connected to the installation space 14 are provided with the first limiting boss 128 and the second limiting boss 137 to enable the object component 10 to be installed on two surfaces of the heat dissipation plate 11. The first side plate 12 is provided with the water inlet 1221 and the water outlet 1222, the first chamber 1241 and the second chamber 1242 are provided with the first flow passage 111 and the second flow passage 112, the second side panel 13 is provided with the connection passages 131, the cooling liquid can enter the first chamber 1241 from the water inlet 1221, and flow into the first flow passage 111, the connection passages 131, the second flow passage 112 and the second chamber 1242, and flow out of the water outlet 1222, to achieve a heat dissipation of the object component 10. The heat dissipation surfaces 113 on both sides of the heat dissipation plate 11 are connected with the object component 10. Multiple object components 10 can be dissipated simultaneously, the heat dissipation efficiency is high.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A heat dissipation bracket, comprising:
a plurality of heat dissipation plates, the plurality of heat dissipation plates defining a length direction, a width direction, and a thickness direction, wherein the plurality of heat dissipation plates is arranged at intervals along the thickness direction, each of the plurality of heat dissipation plates is provided with a first flow passage and a second flow passage separated along the width direction;
a first side plate, provided with a first chamber and a second chamber, wherein the first chamber and the second chamber are arranged at intervals along the width direction, the first side plate is further provided with a water inlet and a water outlet, the water inlet is connected with the first chamber, and the water outlet is connected with the second chamber; and
a second side plate, provided with a plurality of connection passages;
wherein each of the plurality of heat dissipation plates is respectively connected between the first side plate and the second side plate, an installation space is existed between two adjacent heat dissipation plates, and the installation space is configured for installing an object component; and
for each of the plurality of heat dissipation plates, one end of the first flow passage close to the first side plate is connected with the first chamber, one end of the second flow passage close to the first side plate is connected with the second chamber, and one end of the first flow passage close to the second side plate and one end of the second flow passage close to the second side plate are connected with a corresponding connection passage.

2. The heat dissipation bracket as claimed in claim 1, wherein the first side plate comprises a first plate body, a first cover plate, and a sealing structure; the first plate body and the first cover plate are enclosed to form an internal chamber, the sealing structure is arranged in the internal chamber, and the internal chamber is divided into the first chamber and the second chamber by the sealing structure; and the water inlet and the water outlet are respectively arranged on the first cover plate.

3. The heat dissipation bracket as claimed in claim 2, wherein the first plate body comprises a first surface and a second surface, the first surface is located on a side of the first plate body deviating from the second side plate, the second surface is located on a side of the first plate body toward the second side plate; the first plate body is provided with a first groove and a plurality of first installation grooves, the first groove is formed by an inward concave of the first surface, and the plurality of first installation grooves penetrates from a bottom surface of the first groove to the second surface; the first cover plate covers the first groove to form the internal chamber; one end of the plurality of heat dissipation plates near the first side plate are respectively installed on the plurality of first installation grooves;
the first side plate further comprises a convex island structure, and the convex island structure protrudes from the bottom surface of the first groove and abuts against the first cover plate, and the convex island structure is located between two adjacent first installation grooves; the convex island structure comprises a middle island; and the sealing structure comprises two sealing blocks, the two sealing blocks are respectively connected to two sides of the middle island, the middle island and the two sealing blocks jointly form a separation structure, the separation structure divides the internal chamber into the first chamber and the second chamber.

4. The heat dissipation bracket as claimed in claim 3, wherein the convex island structure further comprises a first side island and a second side island; the first side island is located in the first chamber and separated from the middle island to form a first passage; a width of the first passage is less than a width of a portion of the first installation groove located in the first chamber; the second side island is located in the second chamber and separated from the middle island to form a second passage; a width of the second passage is less than a width of a portion of the first installation groove located in the second chamber; and the water inlet is corresponded to the first passage along the length direction, and the water outlet is corresponded to the second passage along the length direction.

5. The heat dissipation bracket as claimed in claim 1, wherein the second side plate comprises a second plate body and a plurality of second cover plates; the second plate body is provided with a plurality of second grooves, and the plurality of second cover plates respectively cover the plurality of second grooves to form the plurality of connection passages.

6. The heat dissipation bracket as claimed in claim 5, wherein the second side plate further comprises a third surface and a fourth surface, the third surface is located on a side of the second plate body toward the first side plate, and the fourth surface is located on a side of the second plate body away from the first side plate; the second plate body is further provided with a second installation groove, the second installation groove penetrates from a bottom surface of the second groove to the third surface; and one end of the plurality of heat dissipation plates near the second side plate are arranged in the second installation groove and connected with the plurality of connection passages.

7. The heat dissipation bracket as claimed in claim 1, wherein the first side plate comprises a second surface, and the second surface is located on a side of the first side plate toward the second side plate; the second side plate comprises a third surface, and the third surface is located on a side of the second side plate toward the first side plate; the first side plate further comprises a first limiting boss protruding from the second surface, and the second side plate further comprises a second limiting boss protruding from the third surface; the first limiting boss is arranged opposite the second limiting boss along the length direction; and the installation space comprises a first subspace and a second subspace, the first subspace and the second subspace are located on either side of the first limiting boss and the second limiting boss respectively, and the first subspace and the second subspace are respectively configured to accommodate one object component.

8. The heat dissipation bracket as claimed in claim 1, wherein the first side plate comprises a second surface, and the second surface is located on a side of the first side plate toward the second side plate; the second side plate comprises a third surface, and the third surface is located on a side of the second side plate toward the first side plate; the first side plate further comprises a first support platform protruding from the second surface, and the second side plate further comprises a second support platform protruding from the third surface; the first support platform and the second support platform are respectively configured to support two ends of the length direction of an object heat dissipation plate which is located at the lowest layer; and a space between the first support platform and the second support platform is configured to be capable of installing one object component.

9. The heat dissipation bracket as claimed in claim 1, wherein each of the plurality of heat dissipation plates comprises two heat dissipation surfaces, the two heat dissipation surfaces are arranged oppositely along the thickness direction, and each of the two heat dissipation surfaces is configured for conducting heat in contact with one object component.

10. An electrical control component comprising a heat dissipation bracket and an object component arranged on the heat dissipation bracket, the heat dissipation bracket comprising:
a plurality of heat dissipation plates, the plurality of heat dissipation plates defining a length direction, a width direction, and a thickness direction, wherein the plurality of heat dissipation plates is arranged at intervals along the thickness direction, each of the plurality of heat dissipation plates is provided with a first flow passage and a second flow passage separated along the width direction;
a first side plate, provided with a first chamber and a second chamber, wherein the first chamber and the second chamber are arranged at intervals along the width direction, the first side plate is further provided with a water inlet and a water outlet, the water inlet is connected with the first chamber, and the water outlet is connected with the second chamber; and
a second side plate, provided with a plurality of connection passages;
wherein each of the plurality of heat dissipation plates is respectively connected between the first side plate and the second side plate, an installation space is existed between two adjacent heat dissipation plates, and the installation space is configured for installing the object component; and
for each of the plurality of heat dissipation plates, one end of the first flow passage close to the first side plate is connected with the first chamber, one end of the second flow passage close to the first side plate is connected with the second chamber, and one end of the first flow passage close to the second side plate and one end of the second flow passage close to the second side plate are connected with a corresponding connection passage; and the object component is thermally connected with at least one of the plurality of heat dissipation plates.

11. The electrical control component as claimed in claim 10, wherein the first side plate comprises a first plate body, a first cover plate, and a sealing structure; the first plate body and the first cover plate are enclosed to form an internal chamber, the sealing structure is arranged in the internal chamber, and the internal chamber is divided into the first chamber and the second chamber by the sealing structure; and the water inlet and the water outlet are respectively arranged on the first cover plate.

12. The electrical control component as claimed in claim 11, wherein the first plate body comprises a first surface and a second surface, the first surface is located on a side of the first plate body deviating from the second side plate, the second surface is located on a side of the first plate body toward the second side plate; the first plate body is provided with a first groove and a plurality of first installation grooves, the first groove is formed by an inward concave of the first surface, and the plurality of first installation grooves penetrates from a bottom surface of the first groove to the second surface; the first cover plate covers the first groove to form the internal chamber; one end of the plurality of heat dissipation plates near the first side plate are respectively installed on the plurality of first installation grooves;
the first side plate further comprises a convex island structure, and the convex island structure protrudes from the bottom surface of the first groove and abuts against the first cover plate, and the convex island structure is located between two adjacent first installation grooves; the convex island structure comprises a middle island; and the sealing structure comprises two sealing blocks, the two sealing blocks are respectively connected to two sides of the middle island, the middle island and the two sealing blocks jointly form a separation structure, the separation structure divides the internal chamber into the first chamber and the second chamber.

13. The electrical control component as claimed in claim 12, wherein the convex island structure further comprises a first side island and a second side island; the first side island is located in the first chamber and separated from the middle island to form a first passage; a width of the first passage is less than a width of a portion of the first installation groove located in the first chamber; the second side island is located in the second chamber and separated from the middle island to form a second passage; a width of the second passage is less than a width of a portion of the first installation groove located in the second chamber; and the water inlet is corresponded to the first passage along the length direction, and the water outlet is corresponded to the second passage along the length direction.

14. The electrical control component as claimed in claim 10, wherein the second side plate comprises a second plate body and a plurality of second cover plates; the second plate body is provided with a plurality of second grooves, and the plurality of second cover plates respectively cover the plurality of second grooves to form the plurality of connection passages.

15. The electrical control component as claimed in claim 14, wherein the second side plate further comprises a third surface and a fourth surface, the third surface is located on a side of the second plate body toward the first side plate, and the fourth surface is located on a side of the second plate body away from the first side plate; the second plate body is further provided with a second installation groove, the second installation groove penetrates from a bottom surface of the second groove to the third surface; and one end of the plurality of heat dissipation plates near the second side plate are arranged in the second installation groove and connected with the plurality of connection passages.

16. The electrical control component as claimed in claim 10, wherein the first side plate comprises a second surface, and the second surface is located on a side of the first side plate toward the second side plate; the second side plate comprises a third surface, and the third surface is located on a side of the second side plate toward the first side plate; the first side plate further comprises a first limiting boss protruding from the second surface, and the second side plate further comprises a second limiting boss protruding from the third surface; the first limiting boss is arranged opposite the second limiting boss along the length direction; and the installation space comprises a first subspace and a second subspace, the first subspace and the second subspace are located on either side of the first limiting boss and the second limiting boss respectively, and the first subspace and the second subspace are respectively configured to accommodate one object component.

17. The electrical control component as claimed in claim 10, wherein the first side plate comprises a second surface, and the second surface is located on a side of the first side plate toward the second side plate; the second side plate comprises a third surface, and the third surface is located on a side of the second side plate toward the first side plate; the first side plate further comprises a first support platform protruding from the second surface, and the second side plate further comprises a second support platform protruding from the third surface; the first support platform and the second support platform are respectively configured to support two ends of the length direction of an object heat dissipation plate which is located at the lowest layer; and a space between the first support platform and the second support platform is configured to be capable of installing one object component.

18. The electrical control component as claimed in claim 10, wherein each of the plurality of heat dissipation plates comprises two heat dissipation surfaces, the two heat dissipation surfaces are arranged oppositely along the thickness direction, and each of the two heat dissipation surfaces is configured for conducting heat in contact with one object component.

19. The electrical control component as claimed in claim 10, wherein the object component comprises an electrical control box.
